(19) United States
(12) Patent Application Publication
(10) Pub. No.: US 2009/0175005 A1
(43) Pub. Date: Jul. 9, 2009

(54) Support, in Particular for an Electronic Power Component, a Power Module Including the Support, an Assembly Including the Module, and an Electrical Member Controlled by the Module

(75) Inventors: Jean-Michel Morelle, Beaugency (FR); Laurent Vivet, Bois d'Arcy (FR); Blaise Rouleau, Paris (FR); Mathieu Medina, Versailles (FR)

Correspondence Address: OLIFF & BERRIDGE, PLC, P.O. BOX 320850, ALEXANDRIA, VA, 22320-4850, US

(73) Assignee: Valeo Etudes Electroniques, Creteil (FR)

(21) Appl. No.: 12/225,875

(22) PCT Filed: Apr. 2, 2007
(86) PCT No.: PCT/FR2007/051053

§ 371 Date: Feb. 6, 2009

(30) Foreign Application Priority Data
Apr. 6, 2006 (FR) 0603049

(51) Int. Cl. H05K 7/20

(52) U.S. Cl. 361/709

(57) ABSTRACT

The support is for fitting on a heat dissipation mass. The support comprises an electrically insulating plate and a heat conductor plate for conducting heat to the heat dissipation mass. In particular, the heat conductor plate is in contact with the electrically insulating plate. The heat conductor plate includes a layer forming a junction with the heat dissipation mass, referred to as its bottom layer, and a layer for stiffening the heat conductor plate, referred to as its intermediate layer. More particularly, the stiffener layer is made of a material of hardness greater than that of the material of the bottom layer.

The present invention relates to a support for an element that is liable to give off heat, in particular for an electronic power component, to a power module including such a support, and to an assembly comprising the power module and an electrical member controlled by the module.

The invention applies more particularly to a power module forming a device for controlling an electrical member of a motor vehicle, such as, for example: an alternator, a motor, etc.

### BACKGROUND OF THE INVENTION

In conventional manner, in order to remove the heat given off by the electronic power component, the support of the power module is designed to be fitted on a heat dissipation mass. In general, the heat dissipation mass is a radiator, e.g. made of aluminum or copper, such that the support needs to insulate the conductive track electrically from the heat dissipation mass, while nevertheless providing heat conduction to said dissipation mass.

Thus, there is proposed in the prior art a support for an element that is liable to give off heat, in particular for an electronic power component, the support being designed to be fitted onto a heat dissipation mass and being of the type comprising an electrically insulating plate and a heat conductor plate for conducting heat to the heat dissipation mass and touching the electrically insulating plate.

By way of example, such a support is described in WO-A-2004/006423.

Thus, that document describes a power module comprising a support carrying an electronic power component. More precisely, the heat conductor plate is made of a thermally conductive metal material and it is designed in particular to stiffen the support. The support is screwed onto a conventional cooling radiator that forms the dissipation mass.

That document proposes optimizing the contact areas between the metal plate and the radiator by lightly curving the face of the metal plate that comes into contact with the radiator. As a general rule, the surface of the radiator is relatively plane and regular such that the curved face deforms and presses against the radiator when the support is screwed to the radiator, thereby providing good contact between the radiator and the support.

Nevertheless, it is desired to fit the support onto a heat dissipation mass that includes surface irregularities, such as spikes, particles, indentations, etc., that are relatively well-marked, which encourages making the metal plate out of a material that is relatively ductile, such as copper, as suggested in that document.

Unfortunately, making the metal plate out of a ductile material runs the risk of the surface irregularities of the dissipation mass puncturing the heat conductor plate and tearing the electrically insulating plate.

Consequently, in order to protect the electrically insulating plate, it is then necessary to provide a heat conductor plate that is relatively thick, thereby correspondingly increasing the size of the support and thus of the power module.

### OBJECTS AND SUMMARY OF THE INVENTION

A particular object of the invention is to propose a support that is more compact, suitable for being fitted on a relatively irregular surface of a heat dissipation mass, while nevertheless guaranteeing relatively good electrical insulation for the support and relatively good transfer of heat from the support to the dissipation mass.

To this end, the invention provides a support carrying at least one element liable to give off heat, the support being of the above-described type, wherein the heat conductor plate comprises a layer forming its junction with the heat dissipation mass, referred to as its bottom layer, and a layer for stiffening the heat conductor plate, referred to as its intermediate layer, said intermediate layer being made of a material presenting hardness greater than that of the material of the bottom layer.

Thus, because the heat conductor plate is made with at least one relatively hard intermediate layer interposed between the insulating plate and the dissipation mass, the insulating plate does not run any risk of being torn by surface irregularities of the dissipation mass.

Furthermore, because the bottom layer is made of a material that is relatively ductile, the contact areas between the heat conductor plate and the dissipation mass are optimized. The bottom and intermediate layers may be relatively thin. As a result the support is compact.

Such a support enables relatively good conduction of heat to the dissipation mass to be guaranteed together with relatively good electrical insulation.

A support of the invention may also include one or more of the following characteristics:
the heat conductor plate includes a layer forming a junction with the electrically insulating plate, referred to as its top layer, said top layer being made of a material having thermal expansion properties similar to those of the bottom layer;
the top layer is substantially identical in thickness to the bottom layer;
the top layer is made of a material identical to that of the bottom layer;
the bottom layer essentially comprises copper;
the support comprises a joint-forming mass interposed between the bottom layer and the heat dissipation mass;
the joint-forming mass comprises a material selected from: fiberglass fabric impregnated with an epoxy resin; a phase change thermoplastic resin; a thermally conductive adhesive including beads of glass; and a double-sided adhesive tape;
the electrically insulating plate comprises a material selected from: fiberglass fabric impregnated with an epoxy resin; a phase change thermoplastic resin; a thermally conductive adhesive including beads of glass; and a double-sided adhesive tape; and
the intermediate layer essentially comprises nickel.

The invention also provides a power module of the type including an electrically conductive track having an electronic power component fitted thereto, and carried by a support, wherein the support is in accordance with the invention, the conductive track being in contact with the insulating plate.

The invention also provides an assembly comprising an electrical member having a body and a power module forming an electrical device for controlling the electrical member, wherein the module is in accordance with the invention and the body of the electrical member forms the heat dissipation mass on which the support is fastened.

The invention can be better understood on reading the following description given purely by way of example and made with reference to the drawing, in which:

### BRIEF DESCRIPTION OF THE DRAWINGS

FIG. 1 is a section view of an assembly including an electrical member and a power module controlling said member of the invention; and

FIG. 2 is a section view of the FIG. 1 power module before said module has been mounted on the electrical member.

### MORE DETAILED DESCRIPTION

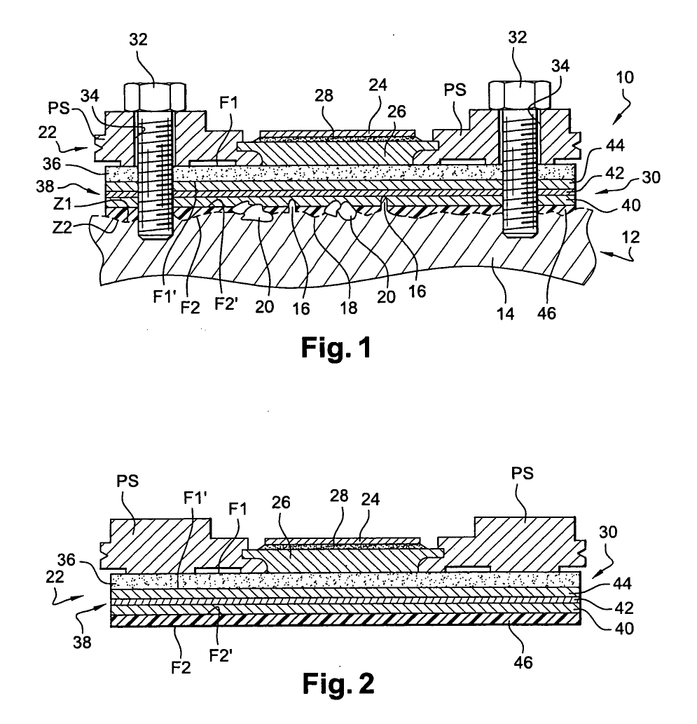

FIG. 1 shows an assembly given overall reference 10.

The assembly 10 comprises an electrical member 12, in particular for a motor vehicle, such as for example: an alternator, a motor, etc.

The electrical member 12 has a body 14. In the example shown, the body 14 presents surface irregularities in a zone Z1, such as, for example: spikes 16, indentations 18, or indeed particles 20 that are detached from the body 14.

The assembly 10 also includes a power module 22. More particularly, the power module 22 forms a device for controlling the electrical member 12.

The power module 22 comprises an electronic power component 24 of the semiconductor chip type.

The power module 22 further includes an electrically conductive track 26 on which the component 24 is fitted.

The conductive track 26 is made of a metal material, e.g. comprising copper, and possibly including a metal coating (not shown) made of a material that includes nickel.

In the example described, the component 24 is soldered onto the conductive track 26. To this end, FIG. 1 shows a mass of solder 28 interposed between the component 24 and the conductive track 26.

The mass of solder 28 may optionally be formed by the coating on the conductive track 26.

In the example shown in FIG. 1, it can be seen that the track 26 is bordered by a portion made of synthetic material PS. This portion made of synthetic material PS forms a mass providing cohesion between the track 26 and other electrically conductive tracks (not shown). In this example, the synthetic material portion PS is overmolded onto the track 26.

The power module 10 also includes a support 30 carrying the track 26 and the synthetic material portion PS. In the example described, the electrically conductive track 26 extends over a first face F1 of the support 30.

Since, in conventional manner, the power component 24 needs to be fed with high current, the track 26 conveys a high current and as a result it is likely to give off heat, in particular in the support 30, but also in the synthetic material portion PS.

Furthermore, the component 24 is also liable to give off heat. Since the mass of solder 28 forms an electrical and thermal joint between the component 24 and the track 26, the heat given off by the component 24 is transmitted essentially towards the track 26.

In order to remove the heat given off by the track 26 and the component 24, the support 30 is fitted onto the body 14 of the electrical member 12, this body 14 then forming a mass for dissipating heat.

Thus, a zone z2 of a second face F2 of the support 30, opposite from its first face F1, comes into contact with the zone Z1 of the body 14 of the electrical member 12.

In the example shown, the support 30 of the module 22 is assembled on the body 14 by means of screws 32. For this purpose, screw holes 34 are formed in the synthetic material portion PS and in the support 30, these screw holes 34 extending into the body 14 of the electrical member 12.

In order to insulate the track 26 electrically from the component 24, the support 30 includes an electrically insulating plate 36.

Preferably, the electrically insulating plate 36 is made of a material selected from a fiberglass fabric impregnated with a glass epoxy resin, a phase change thermoplastic resin, a thermoconductive adhesive including beads of glass, and a double-sided adhesive tape.

The support 30 also includes a plate 38 for conducting heat towards the dissipation mass 14, and touching the electrically insulating plate 36.

In accordance with the invention, the heat conductor plate 38 has a junction layer 40 engaging the body 14 of the electrical member 12, referred to as its bottom layer, and a stiffener layer 42 for stiffening the heat conductor plate 38, referred to as its intermediate layer.

More precisely, the intermediate layer 42 is made of a material that is harder than the material constituting the bottom layer 40.

Preferably, the bottom layer 40 essentially comprises copper while the intermediate layer 42 essentially comprises nickel.

For example, the bottom layer 40 may have a thickness lying in the range 0.5 millimeters (mm) to 1 mm. The intermediate layer 42 has thickness lying in the range 0.25 mm to 0.5 mm.

The heat conductor plate 38 preferably also includes a junction layer 44 engaging the electrically insulating plate 36, referred to as its top layer.

Advantageously, the top layer 44 is made of a material having thermal expansion properties that are similar to those of the bottom layer 40. The three layers 40, 42, and 44 are assembled together, e.g. by being rolled together.

Because the intermediate layer 42 is interposed between two layers 40 and 44 that are made of two materials having similar thermal expansion properties, relative deformation of the layers between one another under the effect of temperature variations is limited.

The top layer 44 is preferably identical in thickness to the bottom layer 40.

The heat conductor plate 38 then has thickness lying in the range 1.25 mm to 2.5 mm.

In the example described, the top layer 44 is made of a material that is identical to that of the bottom layer 40.

Optionally, in order to optimize the surfaces of the contacting zones Z1 of the body 14 and Z2 of the support 30, the support 30 also includes a joint-forming mass 46 that is interposed between the bottom layer 40 and the spike dissipation mass 14.

The joint-forming mass 46 is made of a material that is selected, for example from: fiberglass fabric impregnated with a glass epoxy resin; a phase change thermoplastic resin, a thermally conductive adhesive including glass beads; and a double-sided adhesive tape.

Prior to the module 22 being mounted on the body 14 of the electrical member 12, as shown in FIG. 2, the joint-forming mass 14 may optionally be generally in the form of a plate.

The electrically insulating plate 36 is defined firstly by the first face F1 of the support 30 in contact with the conductive track 26, and secondly by an internal face F1′ in contact with the heat conductor plate 38.

Furthermore, it can be seen in FIG. 2 that the joint-forming mass 46 is defined firstly by the second face F2 of the support 30 that is to be in contact with the body 14 of the electrical member 12, and an internal face F2′ in contact with the heat conductor plate 38.

Since the heat conductor plate 38 is interposed between the electrically insulating plate 36 and the joint-forming mass 46, it is defined firstly by the internal face F1′ of the insulating plate 36 and secondly by the internal face F2′ of the joint-forming mass 46.

It should be observed that the advantages of the invention include the following.

Because of the relatively hard intermediate layer 42 of the heat conductor plate 38, the electrically insulating plate 36 is protected against the surface irregularities of the body 14 of the electrical member 12.

Thus, the electronic power component 24 and the conductive track 26 are insulated electrically from the body 14 of the electrical member 12 effectively by the electrically insulating plate 36 that is protected from any risk of being punctured by the intermediate layer 42.

Because the bottom layer 40 in contact with the body 14 of the electrical member 12 is relatively ductile, the heat conductor plate 38 can deform and adapt to surface irregularities of the body 14 of the member, as can be seen in the figures.

Prior to mounting the module 22 on the body 14, the second face F2 of the support 30 is relatively smooth (see FIG. 2), but after the module 22 has been mounted on the body 14, the second face F2 is deformed by the surface irregularities of the body 14 (see FIG. 1).

The contact area between the zones Z1 and Z2 of the support 30 and of the body 14 of the electrical member 12 is thereby optimized. As a result, the heat conductor plate 38 is effective in transferring heat from the electrically conductive track 26 to the body 14 of the electrical member 12.

What is claimed is:

1. A support for an element that is liable to give off heat, in particular for an electronic power component, the support being designed to be fitted onto a heat dissipation mass and being of the type comprising an electrically insulating plate and a heat conductor plate for conducting heat to the heat dissipation mass and touching the electrically insulating plate, wherein the heat conductor plate comprises a layer forming its junction with the heat dissipation mass, referred to as its bottom layer, and a layer for stiffening the heat conductor plate, referred to as its intermediate layer, said intermediate layer being made of a material presenting hardness greater than that of the material of the bottom layer.

2. A support according to claim 1, wherein the heat conductor plate includes a layer forming a junction with the electrically insulating plate, referred to as its top layer, said top layer being made of a material having thermal expansion properties similar to those of the bottom layer.

3. A support according to claim 2, wherein the top layer is substantially identical in thickness to the bottom layer.

4. A support according to claim 2, wherein the top layer is made of a material identical to that of the bottom layer.

5. A support according to claim 1, wherein the bottom layer essentially comprises copper.

6. A support according to claim 1, having a joint-forming mass for interposing between the bottom layer and the heat dissipation mass.

7. A support according to claim 6, wherein the joint-forming mass comprises a material selected from: fiberglass fabric impregnated with an epoxy resin; a phase change thermoplastic resin; a thermally conductive adhesive including beads of glass; and a double-sided adhesive tape.

8. A support according to claim 1, wherein the electrically insulating plate comprises a material selected from: fiberglass fabric impregnated with an epoxy resin; a phase change thermoplastic resin; a thermally conductive adhesive including beads of glass; and a double-sided adhesive tape.

9. A support according to claim 1, wherein the intermediate layer essentially comprises nickel.

10. A power module of the type including an electrically conductive track having an electronic power component fitted thereon, the module being carried by a support wherein the support is according to claim 1, the conductive track being in contact with the insulating plate.

11. An assembly comprising an electrical member provided with a body and a power module forming an electrical device for controlling the electrical member, wherein the module is according to claim 10 and the body of the electrical member forms the heat dissipation mass on which the support is fitted.
